(19) United States
(12) Patent Application Publication
(10) Pub. No.: US 2026/0057911 A1
(43) Pub. Date: Feb. 26, 2026

(54) MEMORY DEVICE AND METHOD FOR ADJUSTING SIGNAL TRANSMISSION

(71) Applicant: NANYA TECHNOLOGY CORPORATION, New Taipei City (TW)

(72) Inventor: Pin-Hsiu HSIEH, New Taipei City (TW)

(21) Appl. No.: 18/811,749

(22) Filed: Aug. 21, 2024

(51) Int. Cl. G11C 5/06; G11C 5/02

(52) U.S. Cl. CPC G11C 5/06; G11C 5/02

(57) ABSTRACT

A memory device includes a stacked memory, a plurality of conductive vias, and a memory controller. The stacked memory includes a plurality of memory chips. Each memory chip includes at least one memory cell array, a chip identification device, and a signal path switch. The chip identification device is coupled to the at least one memory cell array. The signal path switch is coupled to the chip identification device. The conductive vias penetrate through the stacked memory. The memory controller is coupled to the stacked memory.

### BACKGROUND

### FIELD OF INVENTION

The present disclosure relates to a memory device and a method for adjusting signal transmission.

### DESCRIPTION OF RELATED ART

A plurality of memory dies may be stacked to increase the degree of integration of a memory device. A memory device with three-dimensional structure may store and process a large amount of data. For forming the three-dimensional structure (which may be referred to as 3D stacked memory, or stacked memory), various packaging technologies may be applied to semiconductor dies. In particular, since a through silicon via (TSV) is appropriate for miniaturization and high speed of the memory device, the through silicon via may be used to stack semiconductor dies.

A 3D stacked memory may include coupled layers or packages of dynamic random-access memory (DRAM) memory elements, which may be referred to as a memory stack. Stacked memory may be utilized to provide a great amount of computer memory in a single device or package, where the device or package may also include certain system components, such as a memory controller and central processing unit (CPU).

However, there may a significant cost in the manufacture of 3D stacked memory, in comparison with the cost of simpler memory elements. In the construction of stacked memory devices, a memory die that is without flaws when fabricated may develop flaws in the manufacture of the 3D stacked memory package.

### SUMMARY

One aspect of the present disclosure is to provide a memory device. The memory device includes a stacked memory, a plurality of conductive vias, and a memory controller. The stacked memory includes a plurality of memory chips. Each memory chip includes at least one memory cell array, a chip identification device, and a signal path switch. The chip identification device is coupled to the at least one memory cell array. The signal path switch is coupled to the chip identification device. The conductive vias penetrate through the stacked memory. The memory controller is coupled to the stacked memory.

According to one or more embodiments, the chip identification device includes an identification register.

According to one or more embodiments, the identification register includes a fuse, a one-time programmable memory, a nonvolatile memory, or combinations thereof.

According to one or more embodiments, the memory chips are nonvolatile memory chips or volatile memory chips.

According to one or more embodiments, the nonvolatile memory chips include static random-access memories, ferroelectric random-access memories, read-only memories, flash memories, magnetoresistive random-access memories, or combinations thereof.

According to one or more embodiments, the volatile memory chips include random-access memories, dynamic random-access memories, static random-access memories, or combinations thereof.

According to one or more embodiments, the memory device further includes a plurality of bumps disposed between the conductive vias and the memory controller.

According to one or more embodiments, the bumps are micro bumps, hybrid bumps, bonding pads, or combinations thereof.

According to one or more embodiments, the memory device further includes a plurality of bumps or a plurality of bonding pads disposed between two adjacent memory chips.

According to one or more embodiments, each memory chip further includes an input/output circuit coupled between the chip identification device and the memory cell array.

According to one or more embodiments, memory device further includes a control circuit coupled between the chip identification device of the memory chips and the memory controller.

Another aspect of the present disclosure is to provide a method for adjusting signal transmission. The method includes receiving a memory device including a stacked memory, a plurality of conductive vias penetrating through the stacked memory, and a memory controller coupled to the stacked memory, in which the stacked memory comprises a plurality of memory chips, each memory chip includes at least one memory cell array, a chip identification device coupled to the at least one memory cell array, and a signal path switch coupled to the chip identification device, and the conductive vias respectively allow a signal to transmit. Detecting a first conductive via of the conductive vias for transmitting a first signal is damaged, in which a damage location of the first conductive via is in a first memory chip of the memory chips. Reading a first chip identification of the first memory chip by the memory controller. Adjusting a transmission of the first signal by the memory controller to transmit the first signal through a second conductive via of the conductive vias.

According to one or more embodiments, the method further includes setting a current reference value in the chip identification device of each memory chip, wherein the detecting the first conductive via of the conductive vias for transmitting the first signal is damaged includes: comparing an output current value of the first signal through the first conductive via to the current reference value of the chip identification device of the first memory chip, wherein the output current value is different from the current reference value.

According to one or more embodiments, the method further includes setting a resistance reference value in the chip identification device of each memory chip, wherein the detecting the first conductive via of the conductive vias for transmitting the first signal is damaged includes: comparing an resistance of the first conductive via to the resistance reference value of the chip identification device of the first memory chip, wherein the resistance is different from the resistance reference value.

According to one or more embodiments, the method further includes setting a voltage reference value in the chip identification device of each memory chip, wherein the detecting the first conductive via of the conductive vias for transmitting the first signal is damaged includes: comparing a voltage of the first conductive via to the voltage reference value of the chip identification device of the first memory chip, wherein the voltage is different from the voltage reference value.

According to one or more embodiments, the adjusting the transmission of the first signal by the memory controller to transmit the first signal through the second conductive via of the conductive vias includes: switching off the first conductive via by the signal path switch corresponding to the first conductive via, and switching on the second conductive via by the signal path switch corresponding to the second conductive via.

According to one or more embodiments, the method further includes transmitting a second signal through the first conductive via, wherein the second signal is transmitted to a second memory chip stacked between the first memory chip and the memory controller.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a schematic cross-sectional view illustrating the structure of a memory device according to some embodiments of the present disclosure.

FIG. 2 is a schematic diagram of the relationship between the memory controller and a certain memory chip, in accordance with some embodiments of the present disclosure.

FIG. 3 is a schematic diagram illustrating the signal transmission through the conductive vias in a memory device, in accordance with some embodiments of the present disclosure.

FIG. 4 is a schematic diagram illustrating the signal transmission when a certain node in each memory chip is damaged, in accordance with some embodiments of the present disclosure.

FIG. 5 is a schematic diagram illustrating the signal transmission in the conductive vias when a certain node in one of the conductive vias is damaged, in accordance with some embodiments of the present disclosure.

FIG. 6 is a schematic diagram illustrating signal transmission in the adjusted conductive vias, in accordance with some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Unless otherwise defined, all terms (including technical and scientific terms) used herein have the same meanings as those commonly understood by a person having ordinary skill in the art to which the embodiments of the present disclosure belong. It should be understood that terms, such as those defined in commonly used dictionaries, should be interpreted as having a meaning that is consistent with their meaning in the context of the relevant art and the present disclosure, and should not be interpreted in an idealized or overly formal sense unless expressly so defined herein.

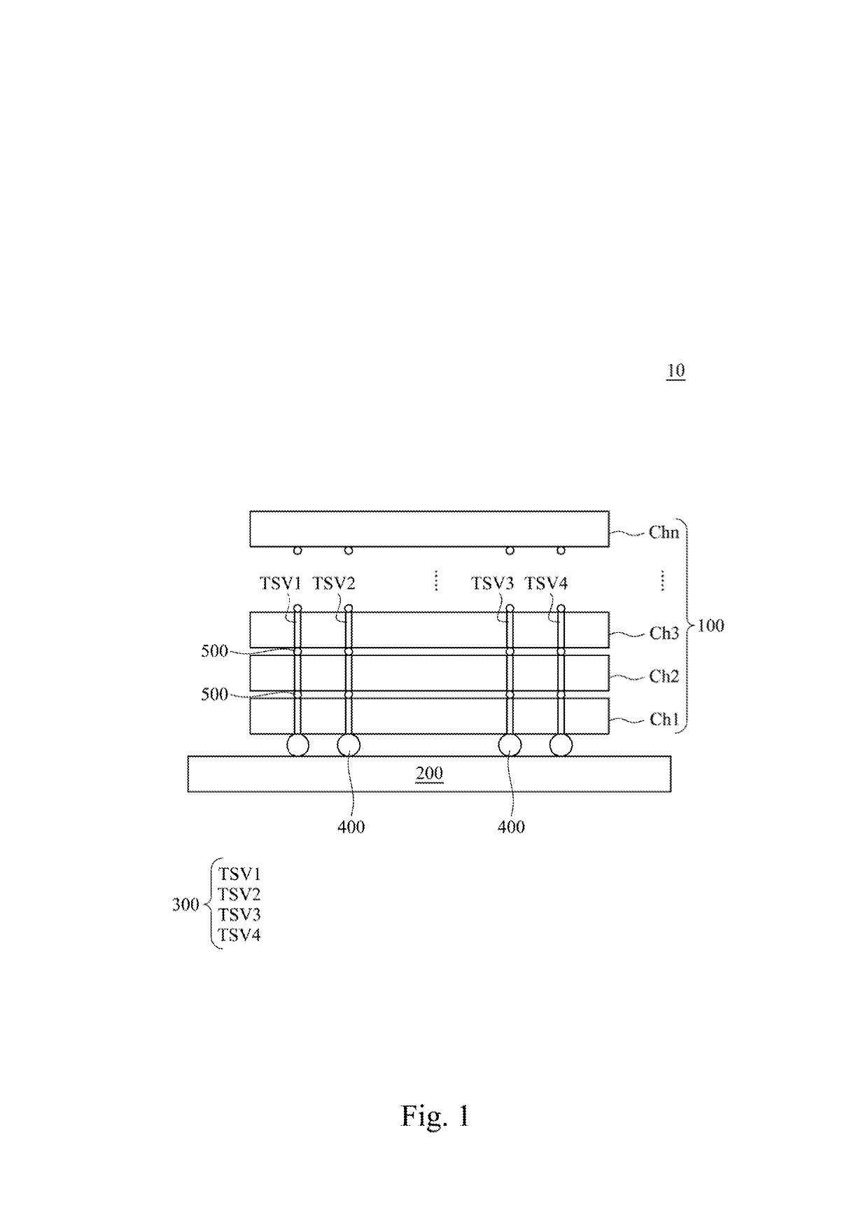

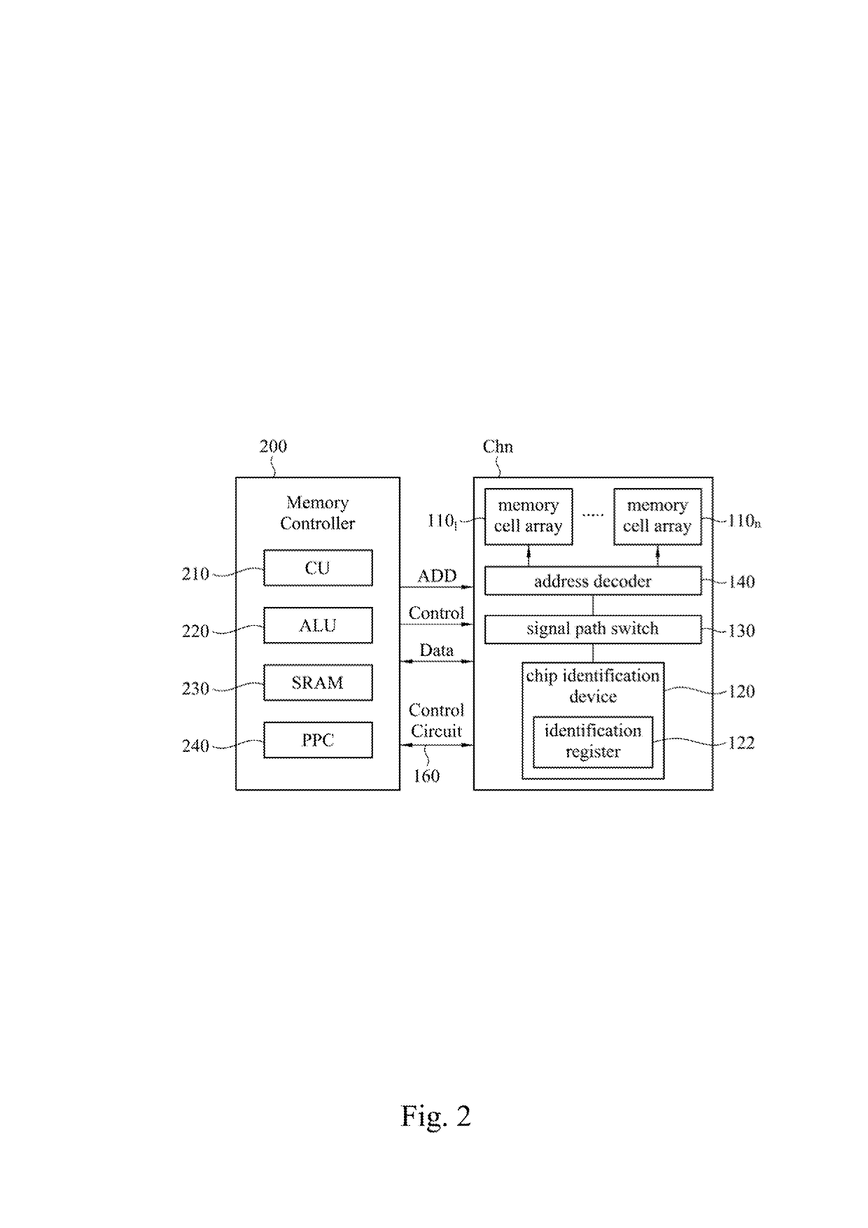

FIG. 1 is a schematic cross-sectional view illustrating the structure of a memory device 10 according to the some embodiments of the present disclosure. FIG. 2 is a schematic diagram of the relationship between the memory controller and a certain memory chip, in accordance with some embodiments of the present disclosure. Referring to FIGS. 1-2, the memory device 10 includes a stacked memory 100, a plurality of conductive vias 300, and a memory controller 200. The stacked memory 100 includes a plurality of memory chips Ch1-Chn, the conductive vias 300 penetrate through the stacked memory 100, and the memory controller 200 is coupled to the stacked memory 100. The three-dimensional (3D) memory device 10 realizes the vertical stacking of memory chips and realizes the vertical interconnection of memory chips through the conductive vias 300. The conductive vias 300 may also be called “through electrodes” or “through silicon via (TSV)”. In other words, the memory device 10 may be a stacked chip-type memory device or a stacked memory device that transmit data and control signals through the conductive vias 300. That is to say, the conductive vias 300 respectively allow a signal to transmit. According to one or more embodiments, the conductive vias 300 includes four conductive vias TSV1-TSV4 shown in FIG. 1, but not limited thereto. According to other embodiments, the conductive vias 300 may include more than four conductive vias, such as ten conductive vias, hundreds conductive vias, and even to thousands conductive vias, which based upon the design requirement.

The memory controller 200 functions to follow an instruction cycle. The instruction cycle is followed by the memory controller 200 to process instructions from boot-up until, for example, a computer has shut down. The instruction cycle is composed of three main stages: a fetch stage, a decode stage, and an execute stage. In some embodiments, the memory controller 200 may be called a logic integrated circuit (IC) or a base die.

According to one or more embodiments, the memory controller 200 includes standard processors, such as a field programmable gate array (FPGA), a graphic processing unit (GPU), a central processing unit (CPU), an application-specific standard part (ASSP), an application specific integrated circuit (ASIC), a micro control unit (MCU), or combinations thereof. However, the present disclosure is not limited thereto. According to one or more embodiments, the memory controller 200 may include another suitable processing device.

According to one or more embodiments, the memory controller 200 includes a logic circuit having a control unit (CU) 210 and an arithmetic logic unit (ALU) 220, a static random-access memory (SRAM) 230, and a processing peripheral circuit (PPC) 240.

In some embodiments, the control unit 210 functions to direct operations within the memory controller 200. According to one or more embodiments, the control unit 210 directs the computer's logic unit, memory, and input and output devices in response to instructions received from a program.

In some embodiments, the arithmetic logic unit 220, coupled to the control unit 210, functions to perform both bitwise and mathematical operations on binary numbers. The arithmetic logic unit 220 is the last component to perform calculations in the memory controller 200. The arithmetic logic unit 220 performs operations on input data based on operands and code received. After the information has been processed by the arithmetic logic unit 220, the processed information is sent to the stacked memory 100.

In some embodiments, the static random-access memory 230, coupled to the control unit 210 and the arithmetic logic unit 220, functions to serve as a cache of the memory controller 200, in which the static random-access memory 230 is a first-level cache. The static random-access memory 230 may be referred to as a second semiconductor memory, if appropriate.

In some embodiments, the processing peripheral circuit 240 functions as a communication interface for communication between the logic circuit of the memory controller 200 and electrical components, such as the stacked memory 100, external to the controller 200. In structure, for example, the logic circuit is not directly coupled to the stacked memory 100. Rather, the logic circuit is directly coupled to the processing peripheral circuit 240, and then indirectly coupled to the stacked memory 100 via the processing peripheral circuit 240.

The stacked memory 100, coupled to the memory controller 200, functions to store instructions required in the instruction cycle and functions to serve as a main memory of the memory controller 200. To be specific, the stacked memory 100 includes a plurality of memory chips Ch1-Chn. As shown in FIG. 1, the stacked memory 100 includes a memory chip Ch1, a memory chip Ch2, a memory chip Ch3, … …, and a memory chip Chn stacked above the memory controller 200 in sequence from bottom to top, where n is equal to or greater than 2. According to one or more embodiments, the memory device 10 further includes a plurality of bumps 400 disposed between the stacked memory 100 and the memory controller 200. In other words, the bumps 400 are disposed between the conductive vias 300 and the memory controller 200. In some embodiments, the bumps 400 are micro bumps, hybrid bumps, bonding pads, or combinations thereof. According to one or more embodiments, the memory device 10 further includes a plurality of bumps 500 or a plurality of bonding pads (not shown) disposed between two adjacent memory chips. In some embodiments, the bumps 500 are micro bumps, hybrid bumps, bonding pads, or combinations thereof. The conductive vias 300 may be electrically connected to the bumps 500 disposed between each of the memory chips Ch1-Chn, and may be electrically connected to the bumps 400 disposed between the first memory chip Ch1 and the memory controller 200. In other words, a segment of one of the conductive vias 300 in the memory chips Ch1-Chn may be electrically connected by the bumps 500.

According to one or more embodiments, the memory chips Ch1-Chn are nonvolatile memory chips or volatile memory chips. According to one or more embodiments, the nonvolatile memory chips include dynamic random-access memories, static random-access memories, ferroelectric random-access memories, read-only memories, or combinations thereof. According to other embodiments, the nonvolatile memory chips include magnetoresistive random access memories (MRAM), resistive random-access memories (ReRAM), conductive bridge memories (CBM), phase-change memories (PCM), nano-tube rain (NRAM), ferroelectric field-effect transistor (FeFET) memories, 3D Xpoint (3DXP) memories, flash memories or combinations thereof. According to one or more embodiments, the volatile memories include dynamic random-access memories (DRAM), random-access memories, static random-access memories, or combinations thereof.

Please refer to FIG. 1 and FIG. 2. More specifically, each of the memory chips Ch1-Chn includes at least one memory cell array 110₁, a chip identification device 120, and a signal path switch 130. As shown in FIG. 2, each of the memory chips Ch1-Chn may include one or more memory cell array 110₁ to 110ₙ, where n is equal to or greater than 2, but not limited thereto. According to one or more embodiments, each of the at least one memory cell array 110₁ to 110ₙ includes a plurality of word lines (not shown), a plurality of bit lines (not shown), and a plurality of memory cells (not shown). The memory cells are arranged in columns and rows. The memory cell is disposed at each intersection of a word line with a bit line, and functions to store data in a digital binary form. The memory cell, for example, includes a storage device for storing data, and a memory transistor for performing cell selection. In an embodiment where the memory chips Ch1-Chn are DRAM, the storage devices include capacitors. In another embodiment where the memory chips Ch1-Chn are MRAM, the storage devices include magnetic tunneling junction (MJT) transistors.

The chip identification device 120 and a signal path switch 130 are part of a memory peripheral circuit (MPC), which functions as a communication interface for communication between the at least one memory cell array 110₁ to 110ₙ and electrical components, such as the memory controller 200, external to the memory chip Ch1-Chn. In structure, for example, the at least one memory cell array 110₁ to 110ₙ is not directly coupled to the memory controller 200. Rather, the at least one memory cell array 110₁ to 110ₙ is directly coupled to the MPC, and then indirectly coupled to the memory controller 200 via the MPC. In addition, the MPC functions to control the at least one memory cell array 110₁ to 110ₙ. According to one or more embodiments, the MPC may further include, for example, a decoder (such as a row decoder and a column decoder), an address buffer (not shown), an input/output (I/O) circuit 150, a clock generator(not shown), a direct-current (DC) generator(not shown), and a sense amplifier (S/A) (not shown). According to one or more embodiments, the input/output circuit 150 is coupled between the chip identification device 120 and the at least one memory cell array 110₁ to 110ₙ.

The chip identification device 120, coupled to the at least one memory cell array 110₁ to 110ₙ, functions to access identification (or identifier) of corresponding memory chip. According to one or more embodiments, the chip identification device 120 includes an identification register 122. For example, the identification register 122 includes a fuse, a one-time programmable memory, or a nonvolatile memory. It can be understood that the identification (or identifier) of each memory chip Ch1-Chn and each memory cell array 110₁ to 110ₙ are independently. According to one or more embodiments, the identification (or identifier) may be amending. By setting up the chip identification device 120, a damage location can be clearly identified when a signal transmission fails.

It should be noted that a conventional DRAM chip may be adopted as the chip identification device 120 with no change. In other words, in the case that the chip identification device 120 of the present disclosure is appended to a DRAM chip, a part of memory cell area may be sufficient for chip identification device 120 and then no additional cost in the manufacturing is necessary. The bit capacity for identification device area may be much smaller than the capacity of generic memories as well as DRAM.

The signal path switch 130, coupled to the chip identification device 120, functions to switch on or switch off the conductive vias 300 in the stacked memory.

Please refer to FIG. 1 and FIG. 2. In operation, the memory controller 200 generates and provides a data signal Data, an address signal ADD, and a memory control signal Control to the MPC to access the at least one memory cell array 110₁ to 110ₙ. In some embodiments, the memory control signal Control includes a command signal. However, the present disclosure is not limited thereto. In some embodiments, the memory control signal Control includes other suitable signals. According to one or more embodiments, the memory device 10 may further include control circuits 160 respectively coupled between the chip identification devices 122 of the memory chips Ch1-Chn and the memory controller 200.

More specifically, each of the memory chips Ch1-Chn further includes an address decoder 140. The chip identification device 120 is coupled to the at least one memory cell array 110₁ to 110ₙ via the signal path switch 130 and the address decoder 140 in order. The address decoder 140 receives the address ADD from the external device (such as memory controller 200) and performs decoding of the address ADD under the control of the control circuits 160.

Another aspect of the present disclosure provides a method for adjusting a signal transmission. The method includes the following steps. First, receiving a memory device, such as the memory device 10 shown in FIGS. 1-2. Then, a first conductive via of the conductive vias for transmitting a first signal is detected damaged, in which a damage location of the first conductive via is in a first memory chip of the memory chips. Next, a first chip identification of the first memory chip is read by the memory controller. A transmission of the first signal is subsequently adjusted by the memory controller to transmit the first signal through a second conductive via of the conductive vias. The method for adjusting the signal transmission is described herein below, in accordance with one or more embodiments of the present disclosure.

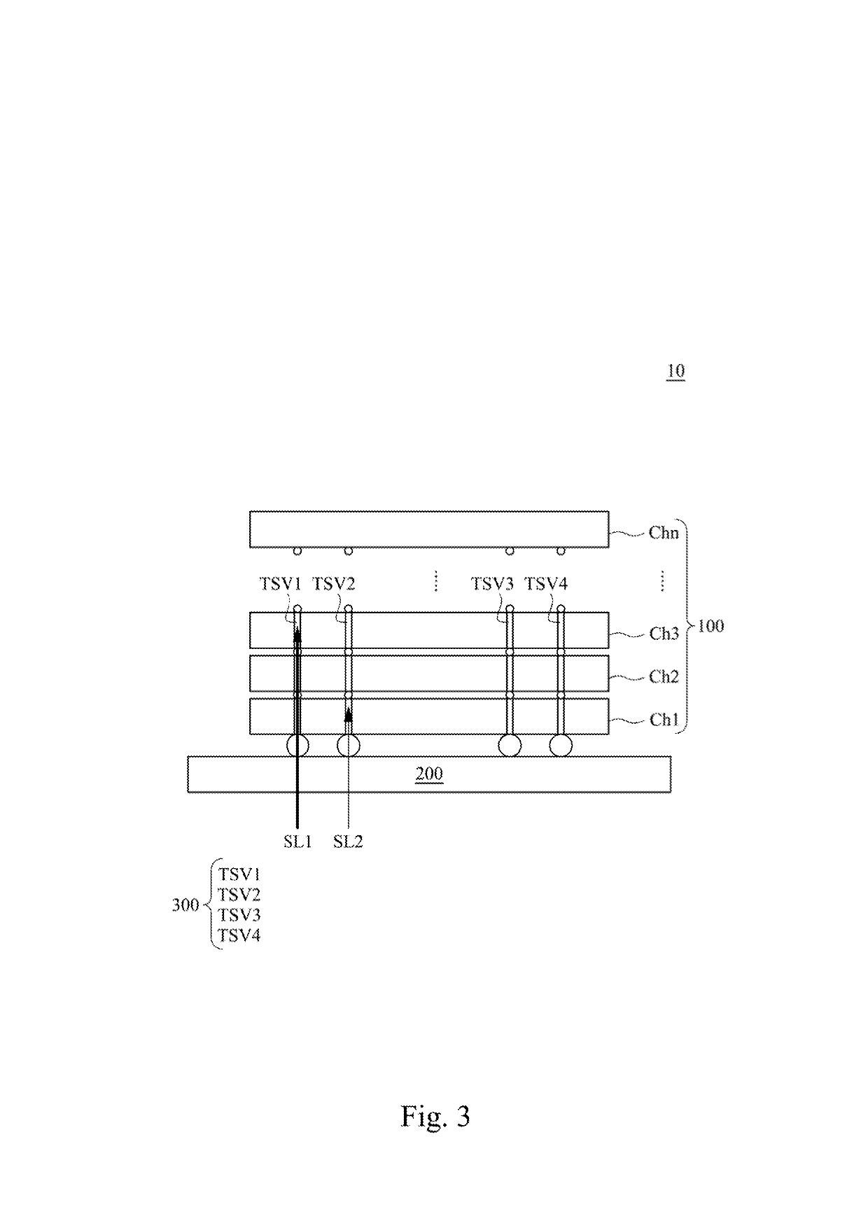

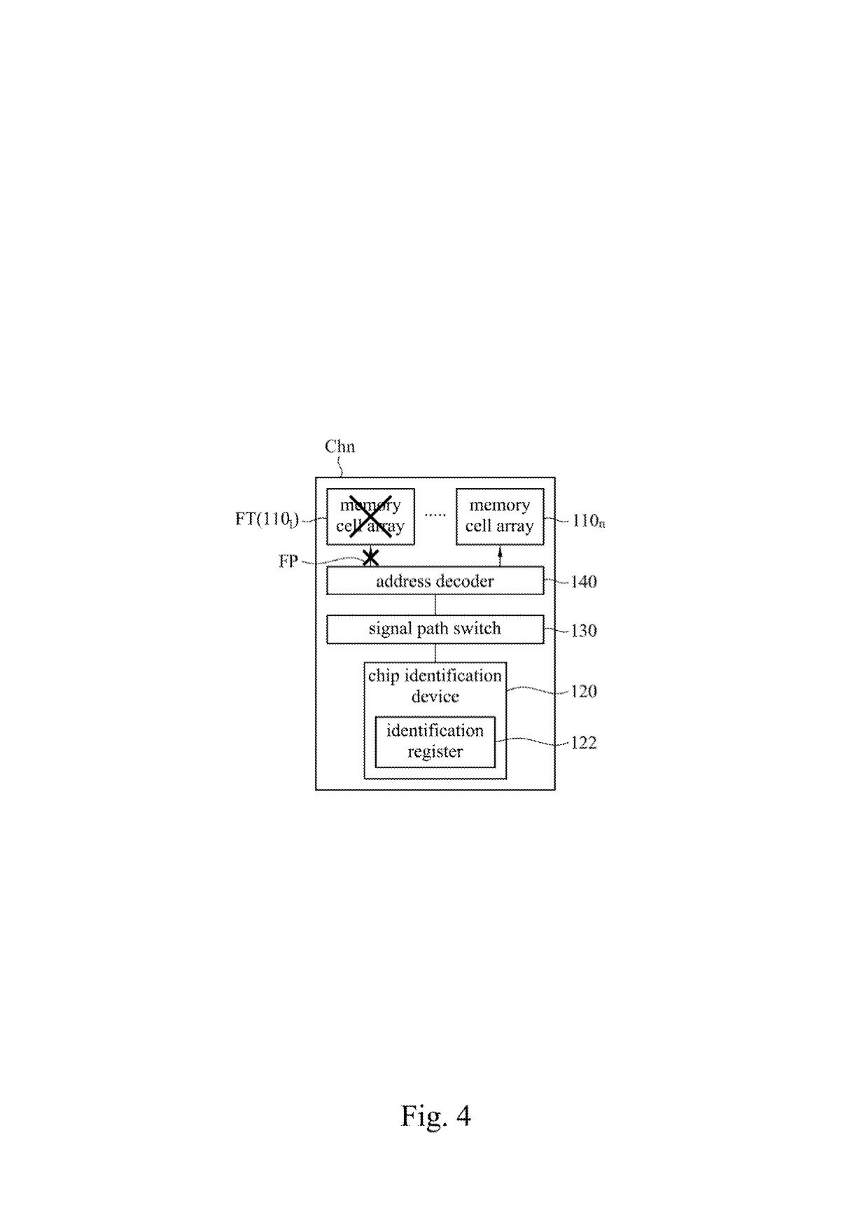

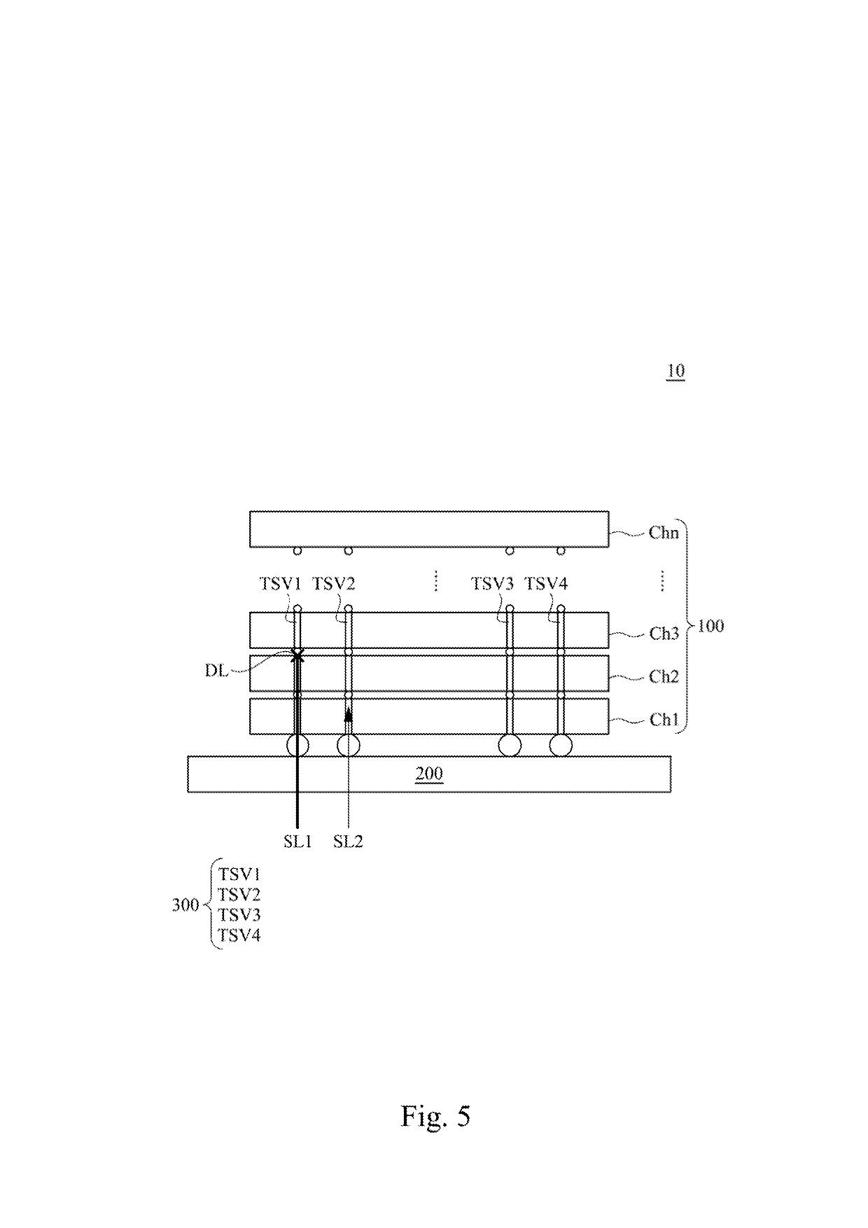

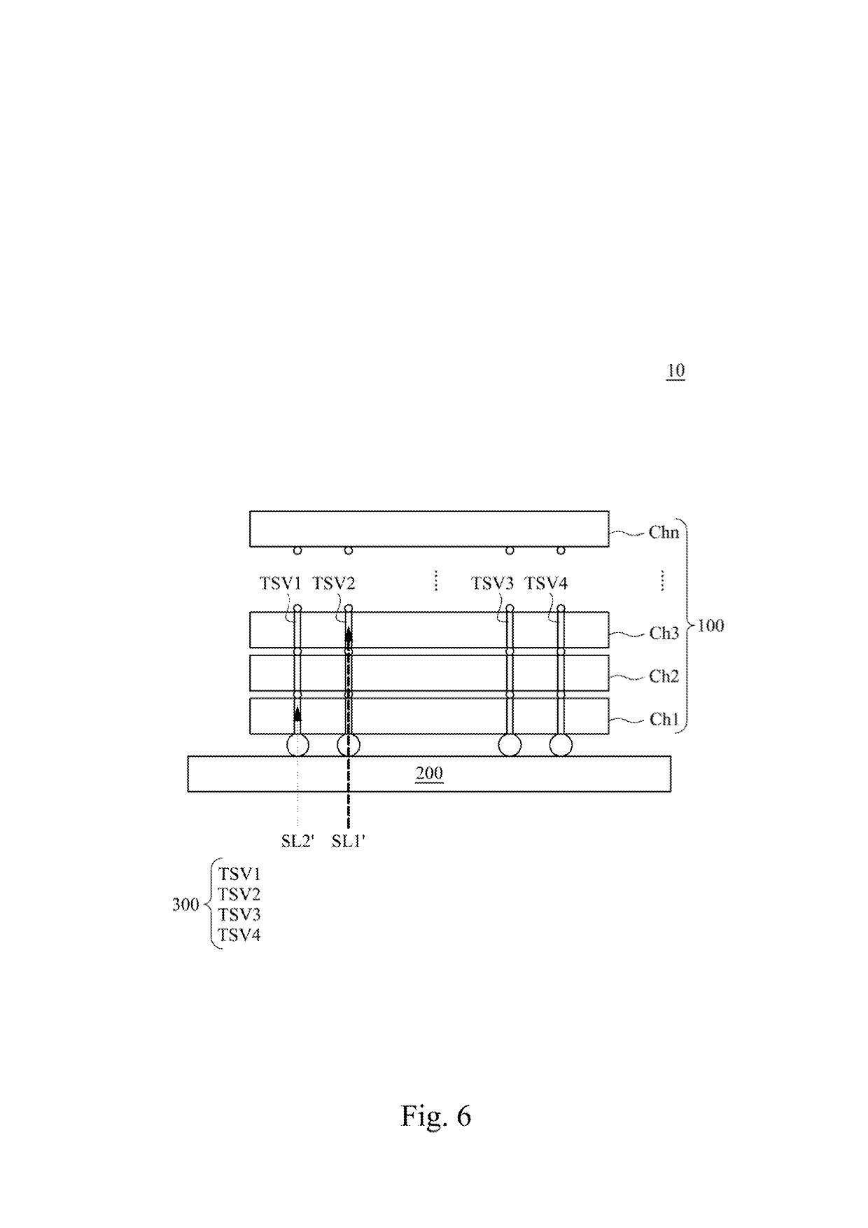

FIG. 3 is a schematic diagram illustrating the signal transmission through the conductive vias in a memory device, in accordance with some embodiments of the present disclosure. FIG. 4 is a schematic diagram illustrating the signal transmission when a certain node in each memory chip is damaged, in accordance with some embodiments of the present disclosure. FIG. 5 is a schematic diagram illustrating the signal transmission in the conductive vias when a certain node in one of the conductive vias is damaged, in accordance with some embodiments of the present disclosure. FIG. 6 is a schematic diagram illustrating signal transmission in the adjusted conductive vias, in accordance with some embodiments of the present disclosure.

Referring to FIGS. 3-6, the original transmission path of the first signal SL1 is shown by the thick solid line, the original transmission path of the second signal SL2 is shown by the thin solid line, the adjusted transmission path of the first signal SL1’ is shown by the thick dashed line, and the adjusted transmission path of the second signal SL2’ is shown by the thin dashed line.

According to one or more embodiments, the first conductive via TSV1 of the conductive vias 300 is used for transmitting the first signal SL1, and the second conductive via TSV2 of the conductive vias 300 is used for transmitting the second signal SL2. The present disclosure is not limited thereto. According to other embodiments, the first signal SL1 may transmit through the second conductive via TSV2 or the third conductive via TSV3 of the conductive vias 300, while the second signal SL2 may transmit through the first conductive via TSV1 or the fourth conductive via TSV4 of the conductive vias 300. It should be noted that the transmission path of the first signal SL1 and the transmission path of the second signal SL2 are independent of each other and do not interfere with each other.

In one embodiment, due to problems that may arise in a manufacturing process or the like, one or more memory cell arrays may be a bad or a damaged memory cell array (such as failed memory cell array FT(110₁) in the memory chip Chn shown in FIG. 4). In another embodiment, due to problems that may arise in a manufacturing process or the like, one or more circuit in each memory chip may be failed or disconnected (such as failed circuit FP in the memory chip Chn shown in FIG. 4). In other embodiments, due to problems that may arise in a manufacturing process or the like, one or more conductive vias 300, among the conductive vias 300, may be a bad or a damaged conductive via (such as an upper node DL in the memory chip Ch2 in the conductive via TSV1 shown in FIG. 5) that cannot operate normally. This cause the first signal SL1 intended to be transmitted to the memory chip Ch3 to be interrupted at the memory chip Ch2. At this time, the chip identification device 120 (shown in FIG. 2) of the memory chip Ch2 may transmit a chip identification corresponding to the memory chip Ch2 to the memory controller 200, so that the controller 200 knows that the damage location is located at the memory chip Ch2.

According to one or more embodiments, the method for adjusting the signal transmission may further include setting a current reference value in the chip identification device 120 (shown in FIG. 2) of each of the memory chips Ch1-Chn. Here, the current reference value represents an ideal current value of the signal. During the transmission of the first signal SL1 through the conductive via TSV1, each of the memory chips Ch1-Chn may calculate or generate a corresponding output current value. Each output current value is compared to the current reference value in the chip identification device 120 (shown in FIG. 2) of each of the memory chips Ch1-Chn. If the output current value does not reach or differ from the current reference value, the memory chip Ch2 is determined to be damaged.

According to one or more embodiments, the method for adjusting the signal transmission may further include setting a resistance reference value in the chip identification device 120 (shown in FIG. 2) of each of the memory chips Ch1-Chn. Here, the resistance reference value represents an ideal resistance value for a signal transmission through a conductive via. During the transmission of the first signal SL1 through the conductive via TSV1, each of the memory chips Ch1-Chn may calculate a resistance of a corresponding segment of the conductive via TSV1 where the first signal SL1 is transmitted. Each resistance is compared to the resistance reference value in the chip identification device 120 (shown in FIG. 2) of each of the memory chips Ch1-Chn. If the resistance does not reach or differ from the resistance reference value, the memory chip Ch2 is determined to be damaged.

According to one or more embodiments, the method for adjusting the signal transmission may further include setting a voltage reference value in the chip identification device 120 (shown in FIG. 2) of each of the memory chips Ch1-Chn. Each voltage is compared to the voltage reference value in the chip identification device 120 (shown in FIG. 2) of each of the memory chips Ch1-Chn. If the voltage does not reach or differ from the voltage reference value, the memory chip Ch2 is determined to be damaged.

After the memory controller 200 reads the chip identification corresponding to the memory chip Ch2, the memory controller 200 may send an instruction to adjust the first signal SL1 transmission path to each memory chip Ch1-Chn. To be specific, the instruction to adjust the first signal SL1 transmission path may be adjusting the transmission of the first signal SL1 by the memory controller 200 to transmit the first signal SL1 through the conductive via TSV2, TSV3, or TSV4 that operates normally. For example, the instruction to adjust the transmission of the first signal SL1 by the memory controller 200 to transmit the first signal SL1 through the conductive via TSV2. In FIG. 6, the adjusted transmission path of the first signal SL1’ is shown by the thick dashed line.

According to one or more embodiments, when the instruction to adjust the transmission of the first signal SL1 by the memory controller 200 to transmit the first signal SL1 through the conductive via TSV2, switching off the conductive via TSV1 by the signal path switch 130 (shown in FIG. 2) corresponding to the conductive via TSV1 and switching on the conductive via TSV2 by the signal path switch 130 (shown in FIG. 2) corresponding to the conductive via TSV2.

According to one or more embodiments, the method for adjusting the signal transmission may further include a second signal SL2 required to be transmitted to the memory chip Ch1. When the conductive via TSV2 originally used to transmit the second signal SL2 is used to transmit the first signal SL1, the second signal SL2 may be adjusted to transmit through the conductive via TSV1. It should be noted that the second signal SL2 is transmitted to the memory chip Ch1 stacked between the memory chip Ch2, which has a damage location of the conductive via TSV1, and the memory controller 200. In other words, in a case of the location of the target memory chip Ch1 that the second signal SL2 needs to reach is lower than the location of the memory chip Ch2 with the damage location of the conductive via TSV1, the first signal SL1 transmitting through the conductive via TSV1 originally may be adjusted to the conductive via TSV2 for transmitting the second signal SL2 originally, and the second signal SL2 transmitting through the conductive via TSV2 originally may be adjusted to the conductive via TSV1 for transmitting the first signal SL1 originally.

The above embodiments provide various advantages. With the above-mentioned method and configuration thereof, it is easier to manage each memory chip and improved the yield of 3D stacked memory. Furthermore, when a damage conductive via is detected, additional metal line routings or redistribution layers (RDLs) for memory chips in different stacking layers may be required to conduct other functioning conductive vias. Therefore, the manufacturing costs may be lowered with the method and configuration thereof of the present disclosure. In addition, the conductive via having a damaged nodes may be used efficiently, so the usage of the redundant conductive via may be reduced, thereby further reducing the number of redundant conductive vias and reducing the proportion of redundant conductive vias in the memory device.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A memory device, comprising:
a stacked memory comprising a plurality of memory chips, wherein each memory chip comprises:
at least one memory cell array; a chip identification device coupled to the at least one memory cell array; and
a signal path switch coupled to the chip identification device; a plurality of conductive vias penetrating through the stacked memory; and
a memory controller coupled to the stacked memory.

2. The memory device of claim 1, wherein the chip identification device comprises an identification register.

3. The memory device of claim 2, wherein the identification register comprises a fuse, a one-time programmable memory, a nonvolatile memory, or combinations thereof.

4. The memory device of claim 1, wherein the memory chips are nonvolatile memory chips or volatile memory chips.

5. The memory device of claim 4, wherein the nonvolatile memory chips comprise static random-access memories, ferroelectric random-access memories, read-only memories, flash memories, magnetoresistive random-access memories, or combinations thereof.

6. The memory device of claim 4, wherein the volatile memory chips comprise random-access memories, dynamic random-access memories, static random-access memories, or combinations thereof.

7. The memory device of claim 1, further comprising a plurality of bumps disposed between the conductive vias and the memory controller.

8. The memory device of claim 7, wherein the bumps are micro bumps, hybrid bumps, bonding pads, or combinations thereof.

9. The memory device of claim 1, further comprising a plurality of bumps or a plurality of bonding pads disposed between two adjacent memory chips.

10. The memory device of claim 1, wherein each memory chip further comprises an input/output circuit coupled between the chip identification device and the memory cell array.

11. The memory device of claim 1, further comprising control circuits respectively coupled between the chip identification devices of the memory chips and the memory controller.

12. A method for adjusting a signal transmission, the method comprising:
receiving a memory device comprising a stacked memory, a plurality of conductive vias penetrating through the stacked memory, and a memory controller coupled to the stacked memory, wherein the stacked memory comprises a plurality of memory chips, each memory chip comprises at least one memory cell array, a chip identification device coupled to the at least one memory cell array, and a signal path switch coupled to the chip identification device, and the conductive vias respectively allow a signal to transmit;
detecting a first conductive via of the conductive vias for transmitting a first signal is damaged, wherein a damage location of the first conductive via is in a first memory chip of the memory chips;
reading a first chip identification of the first memory chip by the memory controller; and
adjusting a transmission of the first signal by the memory controller to transmit the first signal through a second conductive via of the conductive vias.

13. The method for adjusting the signal transmission of claim 12, further comprising:
setting a current reference value in the chip identification device of each memory chip, wherein the detecting the first conductive via of the conductive vias for transmitting the first signal is damaged comprises:
comparing an output current value of the first signal through the first conductive via to the current reference value of the chip identification device of the first memory chip, wherein the output current value is different from the current reference value.

14. The method for adjusting the signal transmission of claim 12, further comprising:
setting a resistance reference value in the chip identification device of each memory chip, wherein the detecting the first conductive via of the conductive vias for transmitting the first signal is damaged comprises:
comparing an resistance of the first conductive via to the resistance reference value of the chip identification device of the first memory chip, wherein the resistance is different from the resistance reference value.

15. The method for adjusting the signal transmission of claim 12, further comprising:
setting a voltage reference value in the chip identification device of each memory chip, wherein the detecting the first conductive via of the conductive vias for transmitting the first signal is damaged comprises:
comparing a voltage of the first conductive via to the voltage reference value of the chip identification device of the first memory chip, wherein the voltage is different from the voltage reference value.

16. The method for adjusting the signal transmission of claim 12, wherein the adjusting the transmission of the first signal by the memory controller to transmit the first signal through the second conductive via of the conductive vias comprises:
switching off the first conductive via by the signal path switch corresponding to the first conductive via; and
switching on the second conductive via by the signal path switch corresponding to the second conductive via.

17. The method for adjusting the signal transmission of claim 12, further comprising:
transmitting a second signal through the first conductive via, wherein the second signal is transmitted to a second memory chip stacked between the first memory chip and the memory controller.
